(19) United States
(12) Patent Application Publication
(10) Pub. No.: US 2024/0409796 A1
(43) Pub. Date: Dec. 12, 2024

(54) CONDENSATION CURE SILICONE ADHESIVE

(71) Applicant: MOMENTIVE PERFORMANCE MATERIALS INC., Niskayuna, NY (US)

(72) Inventors: Kwanho Chang, Clifton Park, NY (US); Yeonseok Cho, Gyeonggi-do (KR); Tiberiu Siclovan, Rexford, NY (US); David Newsham, Round Lake, NY (US)

(21) Appl. No.: 18/206,265

(22) Filed: Jun. 6, 2023

(51) Int. Cl. C09J 183/08; H10K 50/844; H10K 85/10

(52) U.S. Cl. CPC C09J 183/08; H10K 50/844; H10K 85/10

(57) ABSTRACT

A silicone adhesive is shown and described herein. The silicone adhesive composition comprises a silicone resin, a silicone fluid, and an aminosilane. The aminosilane contains two or more amino groups, where the amino groups can be bound to a single silicon atom or may be bound to separate silicon atoms in a silicon core unit. The silicone adhesive compositions are suitable for use as hot melt adhesives and can be used to coat or otherwise encapsulate an article.

### FIELD OF INVENTION

The present invention relates to a silicone adhesive. In particular, the present invention relates to a composition for providing a silicone adhesive. The composition is curable by a condensation reaction and suitable for forming a pressure sensitive adhesive without the need for a conventional platinum catalyst.

### BACKGROUND

Condensation-curable polyorganosiloxanes have been used in a variety of applications and can be employed as materials for adhesive agents, waterproof or moisture proof coating materials, electrical insulating films, construction sealants, and the like. Condensation-curable polyorganosiloxanes have good heat resistance, light resistance, and transparency. These properties make such materials suitable for applications such as, for example, encapsulating light emitting diodes (LEDs). Most commercially available LEDs utilize addition-curable polyorganosiloxanes that are catalyzed by platinum to facilitate the crosslinking reaction. It is known that, under high operational temperatures and high luminous flux, the platinum-catalyzed polyorganosiloxanes often undergo severe discoloration (yellowing) relative to the condensation-curable products. Nevertheless, large amounts of the condensation catalysts, particularly Lewis base catalysts, may lead to discoloration of the condensation curable products as well. Conventional condensation catalysts may impart color to the adhesive or may lead to discoloration of the adhesive when the catalyst degrades and leaves chromophore residues. Therefore, many of the condensation catalysts are not suitable for producing silicone adhesives for applications that demand transparency.

### SUMMARY

The following presents a summary of this disclosure to provide a basic understanding of some aspects. This summary is intended to neither identify key or critical elements nor define any limitations of embodiments or claims. Furthermore, this summary may provide a simplified overview of some aspects that may be described in greater detail in other portions of this disclosure.

In one aspect, provided is a condensation-curable silicone composition for forming an adhesive. The compositions can be employed to form, for example, hot melt adhesives. It may be post-cured by applicators using relevant cure conditions.

In one aspect, provided is a silicone adhesive composition comprising:
a silicone resin;
a silicone fluid; and
an aminosilane of the formula:

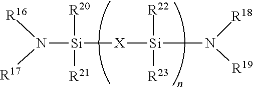

where
R¹⁶, R¹⁷, R¹⁸, and R¹⁹ are each independently selected from hydrogen and a monovalent C1-C14 organic group, where R¹⁶ and R¹⁷ can be taken together to form a ring, optionally containing a heteroatom selected from N, S, and O, and R¹⁸ and R¹⁹ can be taken together to form a ring optionally containing a heteroatom selected from N, S, and O;
R²⁰, R²¹, R²², and R²³ are each independently selected from hydrogen, a monovalent C1-C14 organic group, and —N(R²⁴)(R²⁵), where R²⁴ and R²⁵ are each independently selected from hydrogen and a C1-C14 organic group, where R²⁴ and R²⁵ can be taken together to form a ring, optionally containing a heteroatom selected from N, S, and O;
X is a linker group selected from a divalent C1-C30 organic group, or oxygen; and n is 0 or 1.

In one embodiment, n is 0.

In one embodiment, R¹⁶, R¹⁷, R¹⁸, and R¹⁹ are each hydrogen, and R²⁰ and R²¹ are independently selected from a monovalent C1-C14 alkyl and a monovalent C6-C14 aromatic.

In one embodiment, R¹⁶, R¹⁷, R¹⁸, and R¹⁹ are each independently selected from a monovalent C1-C14 alkyl, and R²⁰ and R²¹ are independently selected from a monovalent C1-C14 alkyl and a monovalent C6-C14 aromatic.

In one embodiment, R¹⁶, R¹⁷, R¹⁸, and R¹⁹ are each independently selected from a monovalent C1-C14 alkyl, and R²⁰ and R²¹ are independently selected from a monovalent C1-C14 alkyl, a monovalent C6-C14 aromatic, and —N(R²⁴)(R²⁵). In one embodiment, R²⁰ is selected from a monovalent C1-C14 alkyl and a C6-C14 aromatic, and R²¹ is selected from —N(R²⁴)(R²⁵). In one embodiment, R¹⁸ and R¹⁹ are each independently selected from —N(R²⁴)(R²⁵).

In one embodiment, n is 1.

In one embodiment, X is a divalent C1-C30 organic group or oxygen.

In one embodiment, X is a divalent C1-C10 alkyl group or a divalent C6-C30 aromatic group.

In one embodiment, R¹⁶, R¹⁷, R¹⁸, R¹⁹, R²⁰, R²¹, R²², and R²³ are each independently selected from a monovalent C1-C14.

In one embodiment, the aminosilane is selected from one or more compounds of the formula:

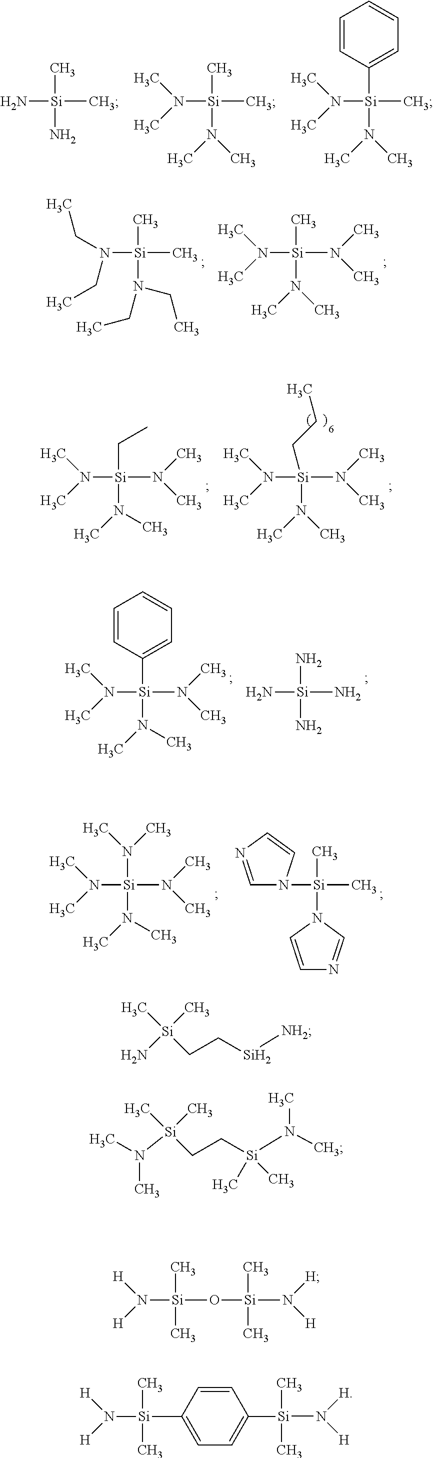

In one embodiment, the aminosilane is present in an amount of from about 100 ppm to about 10 wt. % based on the total weight of the composition.

In one embodiment, the silicone resin comprises aromatic groups.

In one embodiment, the silicone resin is selected from a compound of the formula:

M¹ₐM²_{a′}D¹_{b}D²_{c}T¹_{d}T²ₑQ_{f}

where:
M¹ is (R¹)(R²)(R³)SiO_{1/2}
M² is (R^{1′})(R^{2′})(R^{3′})SiO_{1/2}
D¹ is (R⁴)(R⁵)SiO_{2/2}
D² is (R⁶)(R⁷)SiO_{2/2}
T¹ is (R⁸)SiO_{3/2}
T² is (R⁹)SiO_{3/2}
Q is SiO_{4/2}
R¹, R², R³, R⁴, R⁵, and R⁸ are each independently selected from hydrogen and a monovalent C1-C14 organic group;
R^{1′}, R^{2′}, and R^{3′} are each independently selected from hydrogen, a monovalent C1-C14 organic group, and a monovalent C6-C14 aromatic group, where at least one of R^{1′}, R^{2′}, and R^{3′} is a monovalent C6-C14 aromatic group;
R⁶ and R⁷ are each independently selected from hydrogen, a monovalent C1-C14 organic group, and a monovalent C6-C14 aromatic group, where at least one of R⁶ and R⁷ is a monovalent C6-C14 aromatic group;
R⁹ is selected from a monovalent C6-C14 aromatic group;
a and e are each independently greater than 0; and
a′, b, c, d, and f are each independently 0 or greater.

In one embodiment, a, e, and f are greater than 0.1, and b, c, and d are 0, and a′ is 0 or greater.

In one embodiment, the silicone fluid is of the formula:

HO-D³_{g}D⁴ₕT³ᵢT⁴ⱼ—OH

where:
D³ is (R¹⁰)(R¹¹)SiO_{2/2}
D⁴ is (R¹²)(R¹³)SiO_{2/2}
T³ is (R¹⁴)SiO_{3/2}
T⁴ is (R¹⁵)SiO_{3/2}
   where R¹⁰ and R¹¹, and R¹⁴ are each independently selected from hydrogen and a monovalent C1-C14 organic group;
R¹² and R¹³, and R¹⁵ are each independently selected from hydrogen, a monovalent C1-C14 organic group, and a monovalent C6-C14 aromatic group, where at least one of R¹² and R¹³ is a monovalent C6-C14 aromatic group;
R¹⁵ is selected from a monovalent C6-C14 aromatic group;
h is greater than 0; and
g, i, and j are each independently 0 or greater.

In another aspect, provided is a cured product obtained from curing the silicone adhesive composition.

In still another aspect, provided is an article comprising the cured product disposed on a surface of the article.

In one embodiment, the article is a light emitting diode.

In yet another aspect, provided is a method of making a silicone adhesive comprising:
reacting a mixture of a silicone resin, a silicone fluid, and an aminosilane, wherein the aminosilane is selected from a compound of the formula:

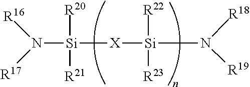

where
R¹⁶, R¹⁷, R¹⁸, and R¹⁹ are each independently selected from hydrogen and a monovalent C1-C14 organic group, where R¹⁶ and R¹⁷ can be taken together to form a ring, optionally containing a heteroatom selected from N, S, and O, and R¹⁸ and R¹⁹ can be taken together to form a ring optionally containing a heteroatom selected from N, S, and O;
R²⁰, R²¹, R²², and R²³ are each independently selected from hydrogen, a monovalent C1-C14 organic group, and —N(R²⁴)(R²⁵), where R²⁴ and R²⁵ are each independently selected from hydrogen and a monovalent C1-C14 organic group, where R²⁴ and R²⁵ can be taken together to form a ring, optionally containing a heteroatom selected from N, S, and O;
X is a linker group selected from a C1-30 alkyl, a C6-C30 aromatic, or oxygen; and
n is 0 or 1.

In one embodiment, the reaction is conducted at a temperature of from about 25 to about 180° C.

The following description discloses various illustrative aspects. Some improvements and novel aspects may be expressly identified, while others may be apparent from the description and drawings.

### DETAILED DESCRIPTION

Reference will now be made to exemplary embodiments. It is to be understood that other embodiments may be utilized, and structural and functional changes may be made. Moreover, features of the various embodiments may be combined or altered. As such, the following description is presented by way of illustration only and should not limit in any way the various alternatives and modifications that may be made to the illustrated embodiments. In this disclosure, numerous specific details provide a thorough understanding of the subject disclosure. It should be understood that aspects of this disclosure may be practiced with other embodiments not necessarily including all aspects described herein, etc.

As used herein, the words “example” and “exemplary” means an instance, or illustration. The words “example” or “exemplary” do not indicate a key or preferred aspect or embodiment. The word “or” is intended to be inclusive rather than exclusive, unless context suggests otherwise. As an example, the phrase “A employs B or C,” includes any inclusive permutation (e.g., A employs B; A employs C; or A employs both B and C). As another matter, the articles “a” and “an” are generally intended to mean “one or more” unless context suggests otherwise.

As used herein, the term, “organic group” generically refers to acyclic, cyclic (or alicyclic) carbon-based group, which can be saturated or unsaturated, and which may be substituted or interrupted with one or more hetero-atoms or functional groups, such as, for example, carboxyl, cyano, hydroxy, halo, and oxy. It will be appreciated that the term can encompass monovalent, divalent, and trivalent groups based on the bonding required within a formula or structure, and that the appropriate valence state is indicated and intended in the context of a given formula or structure.

As used herein, the term “acyclic organic group” means a straight chain or branched organic group, preferably containing from 1 to 60 carbon atoms per group, which may be saturated or unsaturated and which may be optionally substituted or interrupted with one or more hetero-atoms or functional groups, such as, for example, carboxyl, cyano, hydroxy, halo, and oxy. Suitable monovalent acyclic organic groups include, for example, but are not limited to alkyl, alkenyl, alkynyl, hydroxyalkyl, cyanoalkyl, carboxyalkyl, alkyloxy, oxaalkyl, acryloxy, carboxamide and haloalkyl, such as, for example, methyl, ethyl, sec-butyl, tert-butyl, octyl, decyl, dodecyl, cetyl, stearyl, ethenyl, propenyl, butynyl, hydroxypropyl, cyanoethyl, butoxy, 2,5,8-trioxadecanyl, carboxymethyl, chloromethyl, 3,3,3-trifluoropropyl, and the like.

As used herein, the terms “cyclic organic group” or “alicyclic organic group” means an organic group containing one or more saturated and/or unsaturated rings, preferably containing from 4 to 12 carbon atoms per ring, which may optionally be substituted on one or more of the rings with one or more alkyl radicals, each preferably containing from 2 to 6 carbon atoms per alkyl radical, halo radicals, or other functional groups and which, in the case of a monovalent alicyclic hydrocarbon radical containing two or more rings, may be fused rings. Suitable monovalent alicyclic organic groups include, but are not limited to, for example, cyclohexyl, cyclooctyl, norbornenyl, and the like.

As used herein, the term “aromatic group” means a cyclic group containing one or more aromatic rings per radical, which may, optionally, be substituted on the aromatic rings with one or more alkyl groups, each preferably containing from 2 to 6 carbon atoms per alkyl group, halo groups or other functional groups and which, in the case of a monovalent aromatic group containing two or more rings, may be fused rings. Suitable aromatic groups include, but are not limited to, for example, phenyl, tolyl, 2,4,6-trimethylphenyl, 1,2-isopropylmethylphenyl, 1-pentalenyl, naphthyl, anthryl, and the like.

As used herein, the term “aralkyl” means an aromatic derivative of an alkyl group, preferably a (C2-C6) alkyl group, wherein the alkyl portion of the aromatic derivative may, optionally, be interrupted by an oxygen atom, such as, but not limited to, for example, phenylethyl, phenylpropyl, 2-(1-naphthyl)ethyl, phenylpropyl, phenyoxypropyl, biphenyloxypropyl, and the like.

As used herein, viscosity may be evaluated using any suitable method. Unless indicated otherwise, viscosity is measured at 25° C. with a Brookfield (DV1) rotary viscometer.

Numerical values for ranges for a respective component can be combined to form new and non-specified ranges.

Provided is a composition for forming a silicone adhesive. The composition is suitable for forming an adhesive such as, for example, a hot melt adhesive. The composition comprises a silicone resin, a silicone fluid, and an aminosilane. The present aminosilanes provide a manner to cure the silicone composition to provide a silicone adhesive. Use of the present aminosilanes provides a composition that does not require the use of platinum or other precious-metal catalysts.

### Silicone Resin

The present compositions employ silicone resin. In the present composition, silicone resin refers to a silicone material with a network structure. The silicone resin comprises, at least, M units and T units. In embodiments, the silicone resin is an MT resin or an MDT resin or an MTQ resin or an MDTQ resin. The designations “M,” “D,” “T,” and “Q” refer to the type of Si—O groups within the silicone resin and have the general meaning as is used and understood by those in the art. In embodiments, the silicone resin is an aromatic silicone comprising a quantity of aromatic groups, such as, but not limited to, phenyl groups, bound to silicon atoms.

In embodiments, the silicone resin is selected from a compound having the formula:

M¹ₐM²_{a′}D¹_{b}D²_{c}T¹_{d}T²ₑQ_{f}

where:
M¹ is (R¹)(R²)(R³)SiO_{1/2}
M² is (R^{1′})(R^{2′})(R^{3′})SiO_{1/2}
D¹ is (R⁴)(R⁵)SiO_{2/2}
D² is (R⁶)(R⁷)SiO_{2/2}
T¹ is (R⁸)SiO_{3/2}
T² is (R⁹)SiO_{3/2}
Q is SiO_{4/2}
R¹, R², R³, R⁴, R⁵, and R⁸ are each independently selected from hydrogen, a monovalent C1-C14 organic group, and a C6-C14 aromatic group;
R^{1′}, R^{2′}, and R^{3′} are each independently selected from hydrogen, a monovalent C1-C14 organic group, and a monovalent C6-C14 aromatic group, where at least one of R^{1′}, R^{2′}, and R^{3′} is a monovalent C6-C14 aromatic group;
R⁶ and R⁷ are each independently selected from hydrogen, a monovalent C1-C14 organic group, and a monovalent C6-C14 aromatic group, where at least one of R⁶ and R⁷ is a monovalent C6-C14 aromatic group;
R⁹ is selected from a monovalent C6-C14 aromatic group;
a and e are each independently greater than 0; and a′, b, c, d, and f are each independently 0 or greater.

In embodiments, a is from 0.1 to 16, a′ is 0 to 16, b is selected from 0 to 5, c is selected from 0 to 100, d is from 0 to 100, e is 1 to 16, and f is 0.1 to 26.

In one embodiment, a, b, c, d, e, and f are each independently greater than 0; R¹, R², R³, R⁴, R⁵, R⁶, and R⁸ are each independently selected from a monovalent C1-C14 organic group, a monovalent C1-C10 organic group, and a monovalent C1-C6 organic group, and R⁷ and R⁹ are each independently selected from a monovalent C6-C14 aromatic group.

In one embodiment, the silicone resin is an M¹ₐD¹_{b}D²_{c}T¹_{d} resin where R¹, R², R³, R⁴, R⁵, R⁶, and R⁸ are each independently selected from a C1-C4 organic group or a C1-C2 organic group, and R⁷ is selected from a C6-C14 aromatic.

In one embodiment, the silicone resin is resin of the formula M¹ₐD¹_{b}D²_{c}T¹_{d}T²ₑ where R¹, R², R³, R⁴, R⁵, R⁶, and R⁸ are each a methyl group, and R⁷ and R⁹ are each a phenyl group.

In one embodiment, the silicone resin is a resin of the formula M¹ₐD¹_{b}D²_{c}T¹_{d}T²ₑ where R¹, R², R³, R⁴, R⁵, and R⁸ are each a methyl group, and R⁶, R⁷, and R⁹ are each a phenyl group.

In one embodiment, the silicone resin is an M¹ₐD¹_{b}D²_{c}T¹_{d}T²ₑQ_{f} resin where a is from 0.1 to 16, e is 1 to 16, and f is 0.1 to 26, and b, c, and d are 0.

In one embodiment, the silicone resin is a resin of the formula M¹ₐD¹_{b}D²_{c}T¹_{d}T²ₑQ_{f} where a is from 0.1 to 16, c is 0.1 to 100, e is 1 to 16, and f is 0.1 to 26, and b and d are 0.

In one embodiment, the silicone resin is an MTQ resin of the formula M¹ₐT¹_{d}T²ₑQ_{f} where R¹, R², R³, and R⁸ are selected from a monovalent C1-C12 organic group, a monovalent C1-C10 organic group, and monovalent C1-C6 organic group, and R⁹ is selected from a monovalent C6-C14 aromatic group.

In one embodiment, the silicone resin is an MDT resin of the formula M¹ₐD¹_{b}D²_{c}T¹_{d}T²ₑ where R¹, R², R³, R⁴, R⁵, R⁶, and R⁸ are each independently selected from a C1-C4 organic group or a C1-C2 organic group, and R⁷ and R⁹ are each a phenyl group.

In one embodiment, the silicone resin is an MT resin of the formula M¹ₐT¹_{d}T²ₑ resin where R¹, R², R³, and R⁸ are each a methyl group, and R⁹ is a phenyl group.

In one embodiment, a, a′, b, c, d, e, and f are each independently greater than 0; R¹, R², R³, R⁴, R⁵, R⁶, and R⁸ are each independently selected from a monovalent C1-C14 organic group, a monovalent C1-C10 organic group, and a monovalent C1-C6 organic group, R^{1″}, R^{2′}, and R^{3′} are each independently selected from hydrogen, a monovalent C1-C14 organic group, and a monovalent C6-C14 aromatic group, where at least one of R¹, R^{2′}, and R^{3′} is a monovalent C6-C14 aromatic group, and R⁷ and R⁹ are each independently selected from a monovalent C6-C14 aromatic group.

In one embodiment, the silicone resin is an M¹ₐ M²_{a′}D¹_{b}D²_{c}T¹_{d} resin where R¹, R², R³, R⁴, R⁵, R⁶, and R⁸ are each independently selected from a C1-C4 organic group or a C1-C2 organic group, R^{1′}, R^{2′}, and R^{3′} are each independently selected from hydrogen, a monovalent C1-C14 organic group, and a monovalent C6-C14 aromatic group, where at least one of R¹, R^{2′}, and R^{3′} is a monovalent C6-C14 aromatic group, and R⁷ is selected from a C6-C14 aromatic.

In one embodiment, the silicone resin is resin of the formula M¹ₐM²_{a′}D¹_{b}D²_{c}T¹_{d}T²ₑ where R¹, R², R³, R⁴, R⁵, R⁶, and R⁸ are each a methyl group, R^{1′}, R^{2′}, and R^{3′} are each independently selected from methyl and phenyl, where at least one of R¹, R^{2′}, and R^{3′} is a phenyl group, and R⁷ and R⁹ are each a phenyl group.

In one embodiment, the silicone resin is a resin of the formula M¹ₐM²_{a′}D¹_{b}D²_{c}T¹_{d}T²ₑ where R¹, R², R³, R⁴, R⁵, and R⁸ are each a methyl group, R^{1′}, R^{2′}, and R^{3′} are each independently selected from methyl and phenyl, where at least one of R¹, R^{2′}, and R^{3′} is a phenyl group, and R⁶, R⁷, and R⁹ are each a phenyl group.

In one embodiment, the silicone resin is an M¹ₐM²_{a′}D¹_{b}D²_{c}T¹_{d}T²ₑQ_{f} resin where a and a′ are each independently from 0.1 to 16, e is 1 to 16, and f is 0.1 to 26, and b, c, and d are 0.

In one embodiment, the silicone resin is a resin of the formula M¹ₐM²_{a′}D¹_{b}D²_{c}T¹_{d}T²ₑQ_{f} where a and a′ are each independently from is from 0.1 to 16, c is 0.1 to 100, e is 1 to 16, and f is 0.1 to 26, and b and d are 0.

In one embodiment, the silicone resin is an MTQ resin of the formula M¹ₐM²_{a′}T¹_{d}T²ₑQ_{f} where R¹, R², R³, and R⁸ are selected from a monovalent C1-C12 organic group, a monovalent C1-C10 organic group, and monovalent C1-C6 organic group, and R⁹ is selected from a monovalent C6-C14 aromatic group.

In one embodiment, the silicone resin is an MDT resin of the formula M¹ₐM²_{a′}D¹_{b}D²_{c}T¹_{d}T²ₑ where R¹, R², R³, R⁴, R⁵, R⁶, and R⁸ are each independently selected from a C1-C4 organic group or a C1-C2 organic group, R^{1′}, R^{2′}, and R^{3′} are each independently selected from methyl and phenyl, where at least one of R¹, R^{2′}, and R^{3′} is a phenyl group, and R⁷ and R⁹ are each a phenyl group.

In one embodiment, the silicone resin is an MT resin of the formula M¹ₐM²_{a′}T¹_{d}T²ₑ resin where R¹, R², R³, and R⁸ are each a methyl group, R^{1′}, R^{2′}, and R^{3′} are each independently selected from methyl and phenyl, where at least one of R¹, R^{2′}, and R^{3′} is a phenyl group, and R⁹ is a phenyl group.

In embodiments, the organic groups of the silicone resin are from about 2 to about 99 mol %, from about 28 to about 83 mol %, or from about 35 mol % to about 65 mol % aromatic groups.

The silicone resin can have a viscosity, based on 50 wt. % solids in xylene solvent, of from about 5 to about 2000 cP, from about 10 to about 1000 cP, or from about 20 to about 200 cP.

The silicone resin may be present in the composition in an amount of from about 3 to about 70 wt. %, from about 40 to about 65 wt. %, or from about from about 50 to about 60 wt. %.

It will be appreciated that the composition can include a mixture of two or more silicone resins of different formulas and/or different sizes.

### Silicone Fluid

The composition includes a silicone fluid that is selected from silicone fluids containing silanol groups. The silicone fluid can be a linear or branched silicone fluid. In embodiments, the silicone fluid is a linear silicone fluid. The linear silicone fluid may be a hydroxyl terminated silicone.

In one embodiment, the silicone fluid is of the formula:

HO-D³_{g}D⁴ₕT³ᵢT⁴ⱼ—OH

where:
D³ is (R¹⁰)(R¹¹)SiO_{2/2}
D⁴ is (R¹²)(R¹³)SiO_{2/2}
T³ is (R¹⁴)SiO_{3/2}
T⁴ is (R¹⁵)SiO_{3/2}
   where R¹⁰, R¹¹, and R¹⁴ are each independently selected from hydrogen and a monovalent C1-C14 organic group;
R¹² and R¹³ and R¹⁵ are each independently selected from hydrogen, a monovalent C1-C14 organic group, and a monovalent C6-C14 aromatic group, where at least one of R¹² and R¹³ is a monovalent C6-C14 aromatic group;
R¹⁵ is selected from a monovalent C6-C14 aromatic group;
h is greater than 0; and
g, i and j are each independently 0 or greater.

In one embodiment, R¹⁰, R¹¹, and R¹² are each independently selected from hydrogen and a monovalent C1-C14 organic group, a monovalent C1-C10 organic group, and a monovalent C1-C6 organic group; and R¹³ is a monovalent C6-C14 aromatic group.

In one embodiment, R¹⁰ and R¹¹ are each independently selected from hydrogen and a monovalent C1-C2 organic group; and R¹² and R¹³ are each independently selected from a monovalent C6-C14 aromatic group.

In one embodiment, R¹⁰, R¹¹, and R¹² are each a methyl group; and R¹³ is a phenyl group.

In one embodiment, R¹⁰ and R¹¹ are each a methyl group; and R¹² and R¹³ are each a phenyl group.

In embodiments, g is 0 to 1000, 1 to 1000, 5 to 750, 10 to 500, or 25 to 100; h is, 0.1 to 1000, 5 to 750, 10 to 500, or 25 to 100; i is 0 to 5, 1 to 5, or 2 to 4; and j is 0 to 5, 1 to 5, or 2 to 4.

The silicone fluid can have a viscosity of from about 100 to about 1,000,000 cP, from about 1000 to about 100,000 cP, or from about 2000 to about 20,000 cP.

The silicone fluid may be present in the composition in an amount of from about 30 wt. % to about 70 wt. %, from about 35 wt. % to about 60 wt. %, or from about from about 40 wt. % to about 50 wt. %.

It will be appreciated that the composition can include a mixture of two or more silicone fluid materials of different formulas and/or different sizes.

### Aminosilane

The present compositions include an aminosilane. Without being bound to any particular theory, the aminosilane has been found to promote curing of the silicone composition. The aminosilane comprises two or more amine groups. The aminosilane includes a core with one or more silicon atoms and amine groups bonded to at least one of the silicon atoms.

In accordance with the present technology, the aminosilane is of the formula:

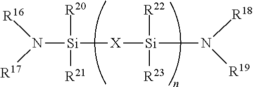

where
R¹⁶, R¹⁷, R¹⁸, and R¹⁹ are each independently selected from hydrogen and a monovalent C1-C14 organic group, where R¹⁶ and R¹⁷ can be taken together to form a ring, optionally containing a heteroatom selected from N, S, and O; and R¹⁸ and R¹⁹ can be taken together to form a ring optionally containing a heteroatom selected from N, S, and O;
R²⁰, R²¹, R²², and R²³ are each independently selected from hydrogen, a monovalent C1-C14 organic group, and —N(R²⁴)(R²⁵), where R²⁴ and R²⁵ are each independently selected from hydrogen and a monovalent C1-C14 organic group, where R²⁴ and R²⁵ can be taken together to form a ring, optionally containing a heteroatom selected from N, S, and O;
X is a linker group selected from a divalent C1-C30 alkyl group, a divalent C6-C30 aromatic radical, or oxygen; and
n is 0 or 1.

In embodiments, n is 0, and the aminosilane has, at least, an N—Si—N bonding group. Example embodiments of an aminosilane where n is 0 include, but are not limited to:
R¹⁶, R¹⁷, R¹⁸, and R¹⁹ are each hydrogen, and R²⁰ and R²¹ are each independently selected from a monovalent C1-C14 alkyl group and a monovalent C6-C14 aromatic group. In one embodiment, R²⁰ and R²¹ are each independently selected from a monovalent C1-C14 alkyl group, a monovalent C1-C10 alkyl group, or a monovalent C1-C6 alkyl group. In one embodiment, R²⁰ is selected from a C1-C14 alkyl group, a C1-C10 alkyl group, or C1-C6 alkyl group, and R²¹ is selected from a C6-C12 aromatic group.
R¹⁶ and R¹⁷ are each hydrogen, R¹⁸ and R¹⁹ are each independently selected from a monovalent C1-C14 alkyl group and a monovalent C6-C14 aromatic group, and R²⁰ and R²¹ are each independently selected from a monovalent C1-C14 alkyl group and a monovalent C6-C14 aromatic group.
R¹⁶, R¹⁷, R¹⁸, and R¹⁹ are each hydrogen, and R²⁰ is selected from —N(R²⁴)(R²⁵), where R²⁴ and R²⁵ are independently selected from hydrogen and a monovalent C1-C14 alkyl group, and R²¹ is selected from a monovalent C1-C14 alkyl group, a monovalent C1-C6 alkyl group, a monovalent C1-C4 alkyl group, a monovalent C6-C14 aromatic group, and —N(R²⁴)(R²⁵) where R²⁴ and R²⁵ are independently selected from a hydrogen and a monovalent C1-C12 alkyl group.
R¹⁶, R¹⁷, R¹⁸, and R¹⁹, are each independently selected from a monovalent C1-C14 alkyl group, a monovalent C1-C10 alkyl group, or a monovalent C1-C6 alkyl group, and R²⁰ and R²¹ are each independently selected from a monovalent C1-C14 alkyl group and —N(R²⁴)(R²⁵), where R²⁴ and R²⁵ are independently selected from hydrogen and a monovalent C1-C14 alkyl group. In one embodiment, R¹⁶, R¹⁷, R¹⁸, and R¹⁹ are each independently selected from a C1-C4 alkyl group or a C1-C2 alkyl group.
R²⁰ and R²¹ are each independently selected from —N(R²⁴)(R²⁵).

In embodiments, n is 1. Example embodiments of an aminosilane where n is 1 include, but are not limited to:
R¹⁶, R¹⁷, R¹⁸, and R¹⁹ are each hydrogen, R²⁰ and R²¹ are each independently selected from a monovalent C1-C14 alkyl and a monovalent C6-C14 aromatic, X is selected from a divalent C1-C30 alkyl, a divalent C1-C20 alkyl, a divalent C1-C15 alkyl, a divalent C1-C10 alkyl, a divalent C6-C30 aromatic, or a divalent C6-C14 aromatic, and R²² and R²³ are each independently selected from hydrogen and a monovalent C1-C14 alkyl. In one embodiment, R²² and R²³ are each hydrogen. In one embodiment, R²² and R²³ are each selected from a monovalent C1-C14 alkyl, a monovalent C1-C10 alkyl, or a monovalent C1-C6 alkyl.
In one embodiment, R²⁰ and R²¹ are each a monovalent C1-C14 alkyl, a C1-C10 alkyl, or C1-C6 alkyl.
In one embodiment, R²⁰ is selected from a monovalent C1-C14 alkyl, a monovalent C1-C4 alkyl, a monovalent C1-C2 alkyl, a monovalent C1-C10 alkyl, or a monovalent C1-C6 alkyl, and R²¹ is selected form a monovalent C6-C14 aromatic.
In one embodiment, R¹⁶ and R¹⁷ are each hydrogen, R¹⁸ and R¹⁹ are each independently selected from a monovalent C1-C14 alkyl and a monovalent C6-C14 aromatic, and R²⁰ and R²¹ are each independently selected from a monovalent C1-C14 alkyl and a monovalent C6-C14 aromatic, X is selected from a divalent C1-C30 alkyl, a divalent C1-C20 alkyl, a divalent C1-C15 alkyl, a divalent C1-C10 alkyl, a divalent C6-C30 aromatic, or a divalent C6-C12 aromatic, and R²² and R²³ are each independently selected from hydrogen and a monovalent C1-C14 alkyl. In one embodiment, R²² and R²³ are each hydrogen. In one embodiment, R²² and R²³ are each selected from a monovalent C1-C14 alkyl, a monovalent C1-C4 alkyl, a monovalent C1-C2 alkyl, a monovalent C2-C10 alkyl, or a monovalent C4-C6 alkyl.
In one embodiment, R¹⁶, R¹⁷, R¹⁸, and R¹⁹ are each hydrogen, and R²⁰ is selected from and —N(R²⁴)(R²⁵), where R²⁴ and R²⁵ are independently selected from hydrogen and a monovalent C1-C14 alkyl, and R¹⁹ is selected from a monovalent C1-C14 alkyl, a monovalent C1-C6 alkyl, a monovalent C1-C4 alkyl, a monovalent C6-C14 aromatic, and —N(R²⁴)(R²⁵) where R²⁴ and R²⁵ are independently selected from a hydrogen and a monovalent C1-C14 alkyl, X is selected from a divalent C1-C30 alkyl, a divalent C1-C20 alkyl, a divalent C1-C15 alkyl, a divalent C1-C10 alkyl, a divalent C6-C30 aromatic, or a divalent C6-C14 aromatic, and R²² and R²³ are each independently selected from hydrogen and a monovalent C1-C14 alkyl. In one embodiment, R²² and R²³ are each hydrogen. In one embodiment, R²² and R²³ are each selected from a monovalent C1-C14 alkyl, a monovalent C1-C4 alkyl, a monovalent C1-C2 alkyl, a monovalent C2-C10 alkyl, or a monovalent C4-C6 alkyl.
In one embodiment, R¹⁶, R¹⁷, R¹⁸, and R¹⁹, are each independently selected from a monovalent C1-C14 alkyl, a monovalent C2-10 alkyl, or a monovalent C4-C6 alkyl, and R²⁰ and R²¹ are each independently selected from a monovalent C1-C14 alkyl and —N(R²⁴)(R²⁵), where R²⁴ and R²⁵ are independently selected from hydrogen and a monovalent C1-C14 alkyl, X is selected from a divalent C1-C30 alkyl, a divalent C1-C20 alkyl, a divalent C1-C15 alkyl, a divalent C1-C10 alkyl, a divalent C6-C30 aromatic, or a divalent C6-C14 aromatic, and R²² and R²³ are each independently selected from hydrogen and a monovalent C1-C14 alkyl. In one embodiment, R²² and R²³ are each hydrogen. In one embodiment R²² and R²³ are each selected from a monovalent C1-C14 alkyl, a monovalent C1-C4 alkyl, a monovalent C1-C2 alkyl, a monovalent C2-C10 alkyl, or a monovalent C4-C6 alkyl.

Some non-limiting examples of suitable aminosilanes include:

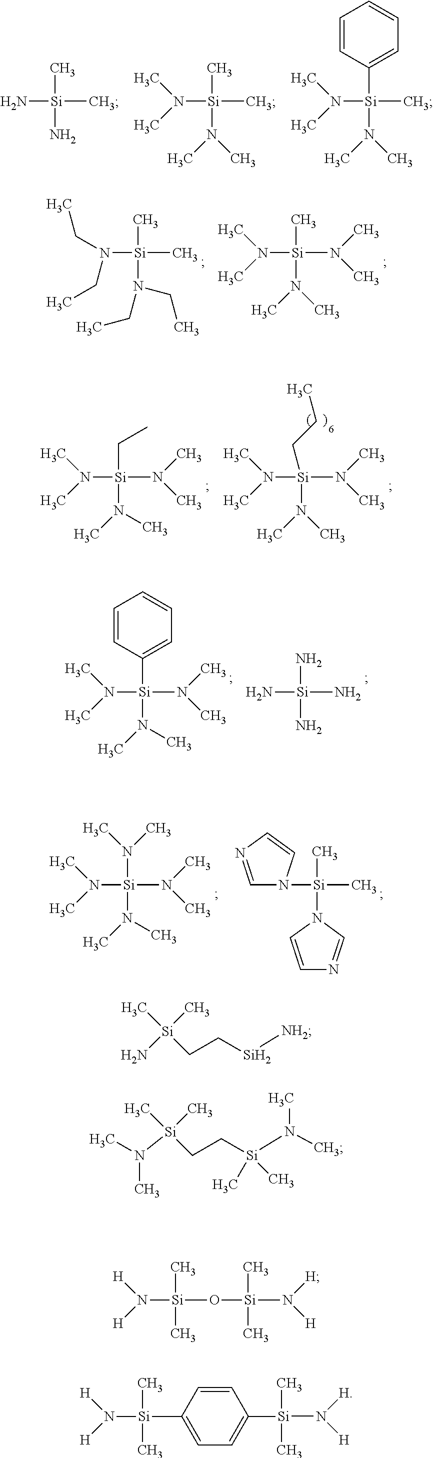

The aminosilane can be present in the composition in an amount of from about 100 ppm to about 10 wt. % based on the total weight of the composition, from about 200 ppm to about 5 wt. % based on the total weight of the composition, from about 500 ppm to about 1.5 wt. % based on the total weight of the composition, from about 750 ppm to about 1.25 wt. % based on the total weight of the composition, from about 0.1 wt. % to about 1 wt. % based on the total weight of the composition, or from about 0.25 wt. % to about 0.75 wt. % based on the total weight of the composition.

It will be appreciated that the composition can include two or more different aminosilanes.

The composition may optionally contain additives, such as pigments, fillers, dyes, plasticizers, thickeners, coupling agents, extenders, volatile organic solvents, wetting agents, tackifiers, crosslinking agents, thermoplastic polymers, UV stabilizers, and the like as may be suitable for a particular purpose or intended application. The typical additives may be used or selected in concentrations as may be suitable to achieve a particular or intended effect for an intended application.

Typical fillers suitable for the composition of the present invention include, but are not limited to, reinforcing fillers such as fumed silica, precipitated silica, clays, talc, aluminum silicates, calcium carbonates, and the like. The plasticizers customarily employed in the condensation curable composition of the present invention can also be used in the invention to modify the properties and to facilitate use of higher filler levels. Exemplary plasticizers include phthalates, diproplyene and diethylene glycol dibenzoates, alkylsulphonate phenols, alkyl phenanthrenes, alkyl/diaryl phosphates and mixtures thereof, and the like. The moisture-curable composition of the present invention can include various thixotropic or anti-sagging agents. Various castor waxes, fumed silica, treated clays and polyamides typify this class of additives.

An adhesive composition can be prepared by mixing the components together. In one embodiment, an adhesive composition is prepared by mixing the silicone resin and the silicone fluid, and subsequently adding the aminosilane to the mixture. The silicone resin and the silicone fluid can be mixed at a temperature of from about 25° C. to about 180° C. The aminosilane can be added to that mixture and facilitate the condensation reaction at a temperature of from about 25° C. to about 150° C. to provide a condensed product. This condensed product may be a partially cured adhesive. The partially cured adhesive can be post-cured to increase the cohesive strength. This can be accomplished by subjecting the partially cured adhesive to a temperature of from about 150° C. to about 180° C.

The adhesive composition can be applied to a surface by any now known or later discovered method. The hot melt adhesive compositions of the instant invention may be applied to various substrates by techniques currently employed for dispensing organic hot melt formulations (e.g., hot melt gun, extrusion, spreading via heated draw-down bars, doctor blades a comma coater, a lip coater, a roll coater, a die coater, a knife coater, a blade coater, a rod coater, curtain coater, a kiss-roll coater, and a gravure coater; screen printing, dipping and casting methods). The composition is heated to a temperature sufficient to induce flow before application. Upon cooling to ambient conditions, the compositions of the present invention are essentially non-tacky, non-slump adhesive compositions which may be used to bond components or substrates to one another. After the desired components are bonded with the hot melt adhesives of the invention, the combination is exposed to elevated temperature so as to cure the hot melt adhesives to build cohesive strength and the modulus of the adhesive. The curing may be carried out using known means at a temperature of about 80 to about 180° C., about 120 to about 180° C., or about 150 to about 180° C., for about 30 minutes to about 500 minutes, about 60 minutes to about 400 minutes, or from about 120 minutes to about 300 minutes.

The amount of the silicone PSA composition to be applied on a surface may be such that the cured adhesive layer has a desired thickness. In one embodiment, the silicone composition is applied such that a cured adhesive layer has a thickness of from about 10 to about 200 m, particularly from about 25 to about 100 m.

In one embodiment, the composition can be used to form a condensed product that may be laminated as a film between release liners. The film can be transferred to a target substrate and subjected to post cure to increase the cohesive strength. Post cure can be accomplished by exposing the film to a temperature of from about 80 to about 180° C.

The present silicone compositions are suitable for use in a variety of applications. The compositions can be employed as, for example, but not limited to, sealants, including hot melt sealants, primers, adhesives including hot melt adhesives and coatings containing such cured compositions. Illustratively, the cured compositions include hot melt compositions. The term, “hot melt composition” as used herein, is a solid material at room temperature that melts upon heating for application to a substrate and re-solidifies upon cooling to form a firm bond between the solid material and the substrate. Hot melt compositions include, but are not limited to, hot melt sealants and hot melt adhesives.

The compositions of this invention find utility in many of the same applications as now being served by silicone hot melt adhesives, particularly in such industries as automotive, electronic, construction, space, and medical. Exemplary electronics applications include but are not limited to the use of silicone hot melt adhesives in portable electronic devices such as smart phones, tablets, and watches. In these areas of application, the instant hot melt adhesives provide bonds which are resistant to hostile environments, such as heat and moisture, and enhance the brightness by filling an air gap under the cover layer.

In one embodiment, the silicone compositions are suitable for use as an encapsulating material for LED elements. A film of the adhesive can be applied to an LED substrate. At an elevated temperature above the glass transition temperature (T_{g}), the film can melt and wet the substrate to generate tight bonding. Post curing by condensing the residual silanol group above the T_{g} increases the cohesive strength and storage modulus of the adhesive.

For LED encapsulating materials, the composition can be provided with a suitable additive as may be desired for a particular use or application. For example, a phosphor may be used to provide a converter material that allows the material to function as a converter layer to convert the wavelength of the photons emitted from the device. The converter particles can be selected to either up-convert or down-convert the wavelength of photons emitted from the diode to change the color of the light emitted from the device. For example, a non-limiting example is providing a phosphor suitable to convert a blue light emission to white light.

The present technology has been described in the foregoing detailed description and with reference to various aspects and embodiments. The technology may be further understood with reference to the following Examples. The Examples are intended to further illustrate aspects and embodiments of the present technology and not necessarily to be limited to such aspects or embodiments.

### Examples

Compositions were prepared according to the following examples. The components employed in the compositions are described in Table 1.

TABLE 1

| Component | Designation | Description |
|---|---|---|
| Silicone | (A-1) Phenyl resin 1 | Dissolved in xylene (50% solid); hydrolysis |
| resin | | product of phenyltrimethoxysilane (Ph-T) 1.4 mol |
| (A) | | (28%), methyltrimethoxysilane (Me-T) |
| | | 1.2 mol (17%), tetraethylorthosilicate (Q) 2.4 mol |
| | | (41%), hexamethyldisiloxane (M) 0.8 mol |
| | | (14%) catalyzed by methane sulfonic |
| | | acid. |
| | (A-2) Phenyl resin 2 | Dissolved in xylene (50% solid); hydrolysis |
| | | product of phenyltrimethoxysilane (Ph-T) 1.6 mol |
| | | (28%), methyltrimethoxysilane (Me-T) |
| | | 1.0 mol (17%), tetraethylorthosilicate (Q) 2.4 mol |
| | | (41%), hexamethyldisiloxane (M) 0.8 mol |
| | | (14%) catalyzed by methane sulfonic |
| | | acid |
| | (A′-3) MQ resin | Dissolved in toluene (60% solid), M/Q = |
| | | 0.89, viscosity 9 to 11.5 cSt, weight average |
| | | molecular weight (Mw) = 7000 to 8000 g/mol |
| Silanol fluid | (B-1) Phenyl silanol fluid | 35 wt. % phenyl, silanol content = 1050 ppm |
| (B) | 1 | RI = 1.474 |
| | (B-2) Phenyl silanol fluid | 43 wt. % phenyl, silanol content = 1100 ppm |
| | 2 | RI = 1.489 |
| | (B′-3) Methyl silanol fluid | Silanol content = 1200 to 1640 ppm, viscosity = |
| | | 2550 to 3570 cSt |
| Aminosilane | (C-1) Dimethyl | |
| (C) | bis(isopropylamino)silane | |
| | (C-2) Bis(dimethylamino) dimethylsilane | 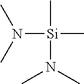 |
| | (C-3) Phenylmethyl bis(dimethylamino)silane | 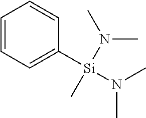 |
| | (C-4) Bis(dimethylamino dimethylsilyl)ethane | 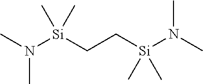 |
| | (C′-5) 1,3,5-Trivinyl- 1,3,5- trimethylcyclotrisilazane | 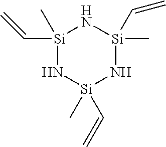 |
| | (C′-6) 1,1,3,3,5,5- Hexamethylcyclo trisilazane | 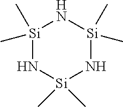 |

### Adhesive Solutions

### Example 1

A 500 mL round bottom flask was charged with 150 g of phenyl resin A-1 (51.2% solid in xylene) and 56.9 g phenyl fluid B-1. The solution was agitated at 80° C. using an overhead stirrer under nitrogen purge for 1 hour. 1.34 g dimethylbis(isopropylamino)silane (C-1) was added to the flask dropwise, and the temperature was increased to 140° C. The solution was gelled while temperature ramped to 120° C.

### Example 2

A 500 mL round bottom flask was charged with 150 g phenyl resin A-1 (51.2% solid in xylene) and 56.9 g phenyl fluid B-1. The solution was agitated at 80° C. using an overhead stirrer under nitrogen purge for 1 hour. 0.33 g dimethylbis(isopropylamino)silane (C-1) was added to the flask dropwise, and the temperature was increased to 140° C. The solution was continuously agitated for 3 hours and then temperature was reduced to 80° C. 60.5 g xylene was charged to the flask, followed by 6.6 g of isopropanol.

### Example 3

A 500 mL round bottom flask was charged with 150 g phenyl resin A-2 (49.9% solid in xylene) and 46.8 g phenyl fluid B-2. Solvent was removed under vacuum using a partial distillation setup at 46° C. for 4 hours. GC-MS showed the product contained 2.5% xylene. 52.2 g propyl propionate was charged to the flask. The mixture was stirred at 100 rpm at 80° C. under nitrogen purge until the mixture was homogenized. 0.43 g dimethylbis(isopropylamino)silane (C-1) was added to the flask dropwise, and the solution was stirred at 80° C. for 1 hour. The solution was further agitated at 100° C. for 3 hours. 3.7 g of isopropanol was added to the flask. The solution continued to be stirred for 3 hours.

### Example 4

A 500 mL round bottom flask was charged with 150 g phenyl resin A-2 (50.8% solid in xylene) and 47.6 g phenyl fluid B-2. Solvent was removed under vacuum using a partial distillation setup at 35° C. for 4 hours. 52.2 g propyl propionate was charged to the flask. The mixture was stirred at 100 rpm at ambient temperature under nitrogen purge until the mixture was homogenized. 0.08 g bis(dimethylamino)dimethylsilane (C-2) was diluted in 1.6 g propyl propionate. The stock solution was added to the flask dropwise at room temperature. After stirring for 10 min, the flask was heated to 60° C. and stirred for 1 hour. The flask was charged with 10 g isopropanol and further stirred for 2.5 hours.

### Example 5

500 mL round bottom flask was charged with 150 g phenyl resin A-2 (50.8% solid in xylene) and 47.6 g phenyl fluid B-2. The mixture was stirred using an overhead stirrer at 100 rpm at ambient temperature under nitrogen purge for 30 min until the mixture was homogenized. 0.07 g phenylmethylbis(dimethylamino)silane (C-3) was diluted in 1.8 g xylene. The stock solution was added to the flask dropwise at room temperature. After stirring for 10 minutes, the flask was heated to 60° C. and stirred for 2 hours. The temperature was raised to 80° C. After the solution was stirred for 30 minutes, 10 g of isopropanol was charged to the flask.

### Example 6

A 500 mL round bottom flask was charged with 150 g phenyl resin A-2 (50.8% solid in xylene) and 47.6 g phenyl fluid B-2. Solvent was removed using a vacuum distillation setup at 35° C. for 3 hours. 52.2 g propyl propionate was charged to the flask. The mixture was stirred at 100 rpm at room temperature under nitrogen purge until the mixture was homogenized. 0.16 g bis(dimethylaminodimethylsilyl)ethane (C-4) was diluted in 1.6 g propyl propionate. The stock solution was added to the flask dropwise at room temperature. After stirring for 20 minutes, the flask was heated to 60° C. and stirred for 2 hours. The temperature was raised to 80° C. After the flask was stirred for 10 minutes, it was charged with 17 g isopropanol and further stirred for 30 minutes.

### Comparative Example 1

A 500 mL round bottom flask was charged with 150 g methyl resin (A′-3) (60.1% solid in toluene) and 66.7 g methyl fluid (B′-3). The mixture was homogenized using an overhead stirrer and reflux dried at 125° C. under nitrogen purge for one hour. The temperature was reduced to 80° C., and 1.34 g dimethylbis(isopropylamino)silane (C-1) was added to the flask dropwise. The temperature was raised back to 130° C., and the mixture was condensed under the reflux condition for 4 hours.

### Comparative Example 2

A 500 mL round bottom flask was charged with 150 g phenyl resin (A-1) (51.2% solid in xylene) and 56.9 g phenyl fluid (B-1). The solution was agitated at 80° C. using an overhead stirrer under nitrogen purge for 1 hour. 2.01 g of 1,3,5-trivinyl-1,3,5-trimethylcyclotrisilazane (C′-5) was added to the flask dropwise, and the temperature was increased to 100° C. The solution was continuously agitated for 3 hours, and the temperature was then reduced to 80° C. 14.1 g of isopropanol was charged to the flask and stirred for 2 hours.

### Comparative Example 3

A 500 mL round bottom flask was charged with 150 g methyl resin (A′-3) (60.1% solid in toluene), 66.7 g methyl fluid (B′-3). The mixture was homogenized using an overhead stirrer and reflux dried at 125° C. under nitrogen purge for one hour. The temperature was reduced to 80° C., and 1.47 g 1,1,3,3,5,5-hexamethylcyclotrisilazane (C′-6) was added to the flask dropwise. The temperature was raised back to 130° C., and the mixture was condensed under the reflux condition for 4 hours.

### Coating Preparation

50 m thick coatings were prepared by casting the solution onto plastic films, e.g., polyethyleneterephthalate (PET), polyimide (PI), and fluorosilicone-coated PET release liners, and drawn down under the Gardner Universal Applicator at a constant speed of 20 mm/s using a TQC Sheen automated coating station. The wet films were dried at 177° C. in a forced-air oven for 10 min before characterization.

### Test Methods

### Peel Force

1″×8″ adhesive-coated samples of PET films were applied to stainless steel panels using a 2 kg constant load roller. The assemblies were annealed at 100° C. and at 140° C., separately, in an oven for 5 min, and cooled to room temperature for 30 minutes before peel was tested at room temperature. 180° peel tests were conducted at a constant peel speed of 12 inch/min using a ChemInstruments AR-2000 adhesion tester. Peel force is reported in grams-force per inch.

### Tack

Tack of the adhesives-coated samples were measured using a TMI Polyken probe tack tester per ASTM D-2979. Tack is reported in grams-force.

### Lap Shear Strength

Lap shear tests were conducted using a Cheminstruments Shear Oven Systems (SOS-8). Adhesive-coated PI films were trimmed into 5″×1″ sample strips. One end of each sample was then applied to a 2″×3″ stainless steel test panel with a 1″×1″ overlap, centered along the bottom edge of the panel. The other end of the sample strip was affixed to a metal weight hanger. The sample was then loaded into the Shear Oven Systems, set to 70° C., and a 1 kg weight was hung from the weight hanger. The lap shear is reported as the time, in minutes, until the sample strip fell from the test panel and triggered a timer switch.

### Dynamic Mechanical Analysis (DMA)

Dynamic mechanical analysis was carried out in an oscillatory shear mode at a 1 Hz frequency using a TA Instruments ARES G2 rheometer. An aliquot of the adhesive film, coated on the fluorosilicone-coated PET liner, was rolled into a ball, and loaded between 8 mm serrated parallel plates. The gap between the plates was set to roughly 0.5 mm. Dynamic temperature ramp was carried out from −100 to +200° C. at a rate of 3° C./min within a linear viscoelastic regime. The storage modulus G′ and loss modulus G″ were measured at 130° C. and the glass transition temperature, T_{g}, was ascribed to at a temperature where the peak tan-δ (G″/G′) value was reached.

The physical properties of the adhesives prepared from the respective compositions are described in Table 2.

TABLE 2

| | | | | | | | Comp. | Comp. | Comp. |
|---|---|---|---|---|---|---|---|---|---|
| | Ex. 1 | Ex. 2 | Ex. 3 | Ex. 4 | Ex. 5 | Ex. 6 | Ex. 1 | Ex. 2 | Ex. 3 |
| Peel force | N/A | <10 | <10 | <10 | <10 | <10 | 1380 | <10 | 950 |
| (gf/in) | | | | | | | | | |
| annealed | | | | | | | | | |
| at 25° C. | | | | | | | | | |
| Peel force | N/A | N/A | 2450 | 770 | 1130 | 1370 | 1360 | <10 | 860 |
| (gf/in) | | | | | | | | | |
| annealed | | | | | | | | | |
| at 100° C. | | | | | | | | | |
| Peel force | N/A | 640 | 2590 | 2310 | 2150 | 2080 | 1390 | <10 | 800 |
| (gf/in) | | | | | | | | | |
| annealed | | | | | | | | | |
| at 140° C. | | | | | | | | | |
| Tack (gf) | N/A | <10 | <10 | <10 | <10 | <10 | 900 | <10 | 420 |
| 25° C. | | | | | | | | | |
| Lap shear | N/A | 5 | 150 | 820 | 1040 | 770 | 0.8 | 2.4 | 7.9 |
| (min) 70° C. | | | | | | | | | |
| G′ (kPa) | 15.6 | 1.3 | 1.8 | 20 | 4.7 | 18 | 0.03 | 260 | 6.0 |
| 130° C. | | | | | | | | | |
| T_{g} (° C.) | 81 | 82 | 98 | 117.8 | 107.9 | 121.0 | N/A | 166.6 | 102.3 |

What has been described above includes examples of the present invention. It is, of course, not possible to describe every conceivable combination of components or methodologies for purposes of describing the present specification, but one of ordinary skill in the art may recognize that many further combinations and permutations of the present specification are possible. Accordingly, the present specification is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

The foregoing description identifies various, non-limiting embodiments of a silicone adhesive composition. Modifications may occur to those skilled in the art and to those who may make and use the invention. The disclosed embodiments are merely for illustrative purposes and not intended to limit the scope of the invention or the subject matter set forth in the claims.

1. A silicone adhesive composition comprising:
a silicone resin;
a silicone fluid; and
an aminosilane of the formula: 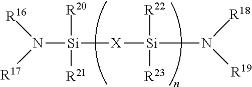
where
R¹⁶, R¹⁷, R¹⁸, and R¹⁹ are each independently selected from hydrogen and a monovalent C1-C14 organic group, where R¹⁶ and R¹⁷ can be taken together to form a ring, optionally containing a heteroatom selected from N, S, and O, and R¹⁸ and R¹⁹ can be taken together to form a ring optionally containing a heteroatom selected from N, S, and O;
R²⁰, R²¹, R²², and R²³ are each independently selected from hydrogen, a monovalent C1-C14 organic group, and —N(R²⁴)(R²⁵), where R²⁴ and R²⁵ are each independently selected from hydrogen and a C1-C14 organic group, where R²⁴ and R²⁵ can be taken together to form a ring, optionally containing a heteroatom selected from N, S, and O;
X is a linker group selected from a divalent C1-C30 organic group, or oxygen; and
n is 0 or 1.

2. The silicone adhesive composition of claim 1, wherein n is 0.

3. The silicone adhesive composition of claim 2, wherein R¹⁶, R¹⁷, R¹⁸, and R¹⁹ are each hydrogen, and R²⁰ and R²¹ are independently selected from a monovalent C1-C14 alkyl and a monovalent C6-C14 aromatic.

4. The silicone adhesive composition of claim 2, wherein R¹⁶, R¹⁷, R¹⁸, and R¹⁹ are each independently selected from a monovalent C1-C14 alkyl, and R²⁰ and R²¹ are independently selected from a monovalent C1-C14 alkyl and a monovalent C6-C14 aromatic.

5. The silicone adhesive composition of claim 2, wherein R¹⁶, R¹⁷, R¹⁸, and R¹⁹ are each independently selected from a monovalent C1-C14 alkyl, and R²⁰ and R²¹ are independently selected from a monovalent C1-C14 alkyl, a monovalent C6-C14 aromatic, and —N(R²⁴)(R²⁵).

6. The silicone adhesive composition of claim 5, wherein R²⁰ is selected from a monovalent C1-C14 alkyl and a C6-C14 aromatic, and R²¹ is selected from —N(R²⁴)(R²⁵).

7. The silicone adhesive composition of claim 5, wherein R¹⁸ and R¹⁹ are each independently selected from —N(R²⁴)(R²⁵).

8. The silicone adhesive composition of claim 1, wherein n is 1.

9. The silicone adhesive composition of claim 8, wherein X is a divalent C1-C30 organic group or oxygen.

10. The silicone adhesive composition of claim 9, wherein X is a divalent C1-C10 alkyl group or a divalent C6-C30 aromatic group.

11. The silicone adhesive composition of claim 8, wherein R¹⁶, R¹⁷, R¹⁸, R¹⁹, R²⁰, R²¹, R²², and R²³ are each independently selected from a monovalent C1-C14.

12. The silicone adhesive composition of claim 1, wherein the aminosilane is selected from one or more compounds of the formula:

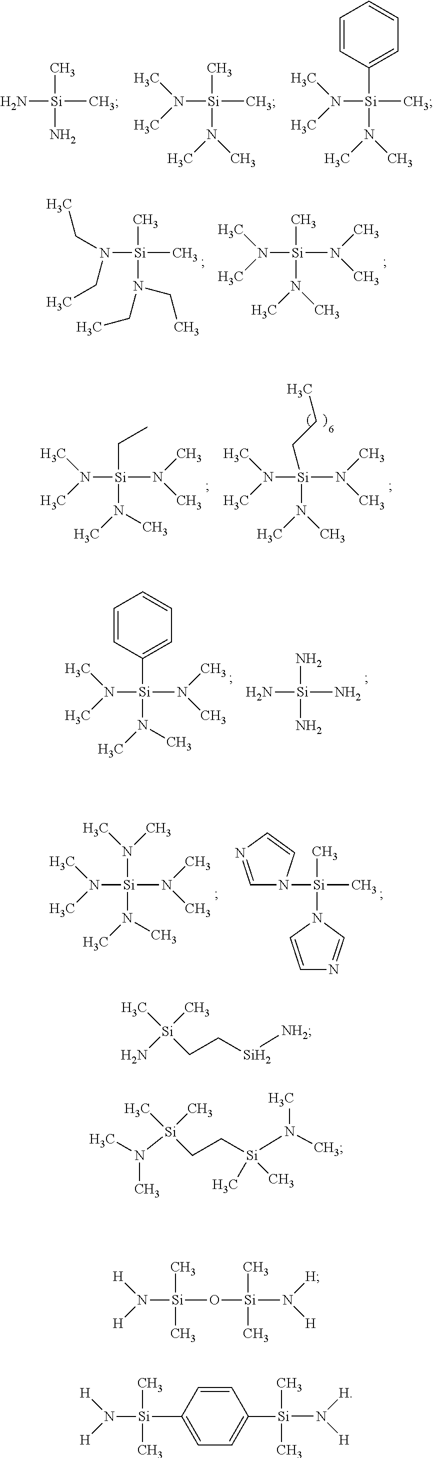

13. The silicone adhesive composition of claim 1, wherein the aminosilane is present in an amount of from about 100 ppm to about 10 wt. % based on the total weight of the composition.

14. The silicone adhesive composition of claim 1, wherein the silicone resin comprises aromatic groups.

15. The silicone adhesive composition of claim 1, wherein the silicone resin is selected from a compound of the formula:
M¹ₐM²_{a′}D¹_{b}D²_{c}T¹_{d}T²ₑQ_{f}
where:
M¹ is (R¹)(R²)(R³)SiO_{1/2}
M² is (R^{1′})(R^{2′})(R^{3′})SiO_{1/2}
D¹ is (R⁴)(R⁵)SiO_{2/2}
D² is (R⁶)(R⁷)SiO_{2/2}
T¹ is (R⁸)SiO_{3/2}
T² is (R⁹)SiO_{3/2}
Q is SiO_{4/2}
R¹, R², R³, R⁴, R⁵, and R⁸ are each independently selected from hydrogen and a monovalent C1-C14 organic group;
R^{1′}, R^{2′}, and R^{3′} are each independently selected from hydrogen, a monovalent C1-C14 organic group, and a monovalent C6-C14 aromatic group, where at least one of R^{1′}, R^{2′}, and R^{3′} is a monovalent C6-C14 aromatic group;
R⁶ and R⁷ are each independently selected from hydrogen, a monovalent C1-C14 organic group, and a monovalent C6-C14 aromatic group, where at least one of R⁶ and R⁷ is a monovalent C6-C14 aromatic group;
R⁹ is selected from a monovalent C6-C14 aromatic group;
a and e are each independently greater than 0; and
a′, b, c, d, and f are each independently 0 or greater.

16. The silicone adhesive composition of claim 15, wherein a, e, and f are greater than 0.1, and b, c, and d are 0, and a′ is 0 or greater.

17. The silicone adhesive composition of claim 1, wherein the silicone fluid is of the formula:
HO-D³_{g}D⁴ₕT³ᵢT⁴ⱼ—OH
where:
D³ is (R¹⁰)(R¹¹)SiO_{2/2}
D⁴ is (R¹²)(R¹³)SiO_{2/2}
T³ is (R¹⁴)SiO_{3/2}
T⁴ is (R¹⁵)SiO_{3/2}
where R¹⁰ and R¹¹, and R¹⁴ are each independently selected from hydrogen and a monovalent C1-C14 organic group;
R¹² and R¹³, and R¹⁵ are each independently selected from hydrogen, a monovalent C1-C14 organic group, and a monovalent C6-C14 aromatic group, where at least one of R¹² and R¹³ is a monovalent C6-C14 aromatic group;
R¹⁵ is selected from a monovalent C6-C14 aromatic group;
h is greater than 0; and
g, i, and j are each independently 0 or greater.

18. A cured product obtained from curing the silicone adhesive composition of claim 1.

19. An article having the cured product of claim 20 disposed on a surface of the article.

20. The article of claim 19, wherein the article is a light emitting diode.

21. The article of claim 20, wherein the cured product encapsulates the light emitting diode.

22. A method of making a silicone adhesive comprising:
reacting a mixture of a silicone resin, a silicone fluid, and an aminosilane, where the aminosilane is selected from a compound of the formula: 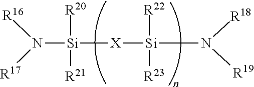
where
R¹⁶, R¹⁷, R¹⁸, and R¹⁹ are each independently selected from hydrogen and a monovalent C1-C14 organic group, where R¹⁶ and R¹⁷ can be taken together to form a ring, optionally containing a heteroatom selected from N, S, and O, and R¹⁸ and R¹⁹ can be taken together to form a ring optionally containing a heteroatom selected from N, S, and O;
R²⁰, R²¹, R²², and R²³ are each independently selected from hydrogen, a monovalent C1-C14 organic group, and —N(R²⁴)(R²⁵), where R²⁴ and R²⁵ are each independently selected from hydrogen and a monovalent C1-C14 organic group, where R²⁴ and R²⁵ can be taken together to form a ring, optionally containing a heteroatom selected from N, S, and O;
X is a linker group selected from a C1-30 alkyl, a C6-C30 aromatic, or oxygen; and
n is 0 or 1.

23. The method of claim 22, wherein the reaction is conducted at a temperature of from about 25 to about 180° C.
